(19) United States
(12) Patent Application Publication
(10) Pub. No.: US 2009/0245437 A1
(43) Pub. Date: Oct. 1, 2009

(54) SAMPLE RATE CONVERTER AND RCEIVER USING THE SAME

(75) Inventors: Masanori FURUTA, Mishima-shi (JP); Takafumi Yamaji, Yokohama-shi (JP); Takeshi Ueno, Kawasaki-shi (JP)

Correspondence Address: Ohlandt, Greeley Ruggiero & Perle, L.L.P.;One Landmark Square, 10th Floor, Stamford, CT, 06901-2682, US

(73) Assignee: Kabushiki Kaisha Toshiba

(21) Appl. No.: 12/369,781

(22) Filed: Feb. 12, 2009

(30) Foreign Application Priority Data
Mar. 27, 2008 (JP) 2008-083594

(51) Int. Cl. H04L 27/06; H03M 7/00

(52) U.S. Cl. 375/344; 341/61

(57) ABSTRACT

A sample rate converter includes a multiplexer to select either one of an input signal and a first feedback signal, and to obtain a selected input signal, a decimator performing decimation on an Nth-order integration signal to generate an output signal, an interpolator performing interpolation on the output signal to generate a second feedback signal, a multiplier which multiplies the second feedback signal by a coefficient to generate a multiplication signal, a subtractor which subtracts the multiplication signal from the selected input signal to generate a residual signal, an adder which adds the residual signal to a third feedback signal to sequentially generate 1st-order to Nth-order integration signals, a register circuit configured to hold the integration signals, a multiplexer to select the first feedback signal from the integration signals that the register hold, and a multiplexer to select the third feedback signal from the integration signals that the register hold.

### CROSS-REFERENCE TO RELATED APPLICATIONS

This application is based upon and claims the benefit of priority from prior Japanese Patent Application No. 2008-083594, filed Mar. 27, 2008, the entire contents of which are incorporated herein by reference.

### BACKGROUND OF THE INVENTION

1. Field of the Invention

The present invention relates to a sample rate converter that converts a sample rate for input signals and a receiver using the sample rate converter.

2. Description of the Related Art

When a sample rate converter down-samples high-rate digital signals that are output signals from an oversampling A/D converter, a folding component (noise) of quantization noise may be generated in a desired signal band. Such folding noise may reduce the signal-to-noise ratio (SNR). A filter with high phase linearity, for example, a sinc filter is conventionally used to suppress the folding noise before the down-sampling.

Normally, a higher-order filter can more effectively suppress the folding noise. A decimation filter described in JP-A H10-209815 (KOKAI) uses a sinc filter composed of a plurality of cascaded 1st-order integration circuits to suppress the folding noise.

The decimation filter described in JP-A H10-209815 (KOKAI) includes the same number of cascaded integration circuits as sinc filters. That is, circuit area increases consistently in accordance with the number of sinc filters. Furthermore, when a sinc filter is actually constructed by cascading a plurality of integration circuits together, the area of circuits located close to an output of the filter is larger. Thus, using a high-order sinc filter for the decimation filter described in JP-A H10-209815 (KOKAI) is difficult.

### BRIEF SUMMARY OF THE INVENTION

According to an aspect of the invention, there is provided a sample rate converter performing Nth-order (N is a natural number of at least 2) integration on an input signal and then converting a sample rate for the input signal to generate an output signal, comprising: a first selection unit configured to select either one of the input signal and a first feedback signal corresponding to an Mth-order (M is a natural number of 1≦M<N) integration signal repeatedly utilized to obtain an Nth-order integration signal, and to obtain a selected input signal; a decimator performing decimation on the Nth-order integration signal according to a decimation rate to generate the output signal; an interpolator performing interpolation corresponding to the decimation rate, on the output signal to generate a second feedback signal; a second selection unit configured to sequentially select N coefficients one by one within a cycle corresponding to the sample rate to obtain a selected coefficient; a multiplier which multiplies the second feedback signal by the selected coefficient to generate a multiplication signal; a subtractor which subtracts the multiplication signal from the selected input signal to generate a residual signal; an adder which adds the residual signal to a third feedback signal with an order greater than that of the selected input signal by one to sequentially generate 1st-order to Nth-order integration signals one by one; a register circuit configured to hold the 1st-order to Nth-order integration signals; a third selection unit configured to select the first feedback signal from the 1st-order to Nth-order integration signals that the register hold; and a fourth selection unit configured to select the third feedback signal from the 1st-order to Nth-order integration signals that the register hold.

According to another aspect of the invention, there is provided a sample rate converter performing Nth-order (N is an even number of at least 4) integration on an input signal and then converting a sample rate for the input signal to generate an output signal, comprising: a first selection unit configured to select either one of the input signal and a first feedback signal corresponding to an Mth-order (M is an even number of 1≦M<N) integration signal repeatedly utilized to obtain an Nth-order integration signal, and to obtain a selected input signal; a decimator performing decimation on the Nth-order integration signal according to a decimation rate to generate the output signal; an interpolator performing interpolation corresponding to the decimation rate, on the output signal to generate a second feedback signal; a second selection unit configured to sequentially select N/2 coefficients one by one within a cycle corresponding to the sample rate to obtain a first selected coefficient; a first multiplier which multiplies the second feedback signal by the first selected coefficient to generate a first multiplication signal; a first subtractor which subtracts the first multiplication signal from the selected input signal to generate a first residual signal; a first adder which adds the first residual signal to a third feedback signal with an order greater than that of the selected input signal by one to sequentially generate odd number-order integration signals one by one; a first register circuit configured to hold the odd number-order integration signals; a third selection unit configured to select the third feedback signal from the odd number-order integration signals that the first register hold; a fourth selection unit configured to sequentially select N/2 second coefficients one by one within the cycle to obtain a second selected coefficient; a second multiplier which multiplies the second feedback signal by the second selected coefficient to generate a second multiplication signal; a second subtractor which subtracts the second multiplication signal from each of the odd number-order integration signals to generate a second residual signal; a second adder which adds the second residual signal to a fourth feedback signal with an order greater than that of each of the odd number-order signals by one to sequentially generate even number-order integration signals one by one; a second register circuit configured to hold the even number-order integration signals; a fifth selection unit configured to select the fourth feedback signal from the even number-order integration signals; and a sixth selection unit configured to select the first feedback signal from the even number-order integration signals that the second register hold.

### BRIEF DESCRIPTION OF THE SEVERAL VIEWS OF THE DRAWING

FIG. 1 is a block diagram showing a sample rate converter according to a first embodiment;

FIG. 2 is a diagram showing an example of a timing chart of various signals processed by the sample rate converter in FIG. 1;

FIG. 3 is a block diagram showing a sample rate converter according to a second embodiment;

FIG. 4 is a diagram showing an example of a timing chart of various signals processed by the sample rate converter in FIG. 3;

FIG. 5 is a diagram showing an example of a multiplier coefficient used by the sample rate converters in FIGS. 1 and 3;

FIG. 6 is a block diagram showing a receiver according to a third embodiment; and

FIG. 7 is a block diagram showing a receiver according to a fourth embodiment.

### DETAILED DESCRIPTION OF THE INVENTION

Embodiments of the present invention will be described below with reference to the drawings.

### First Embodiment

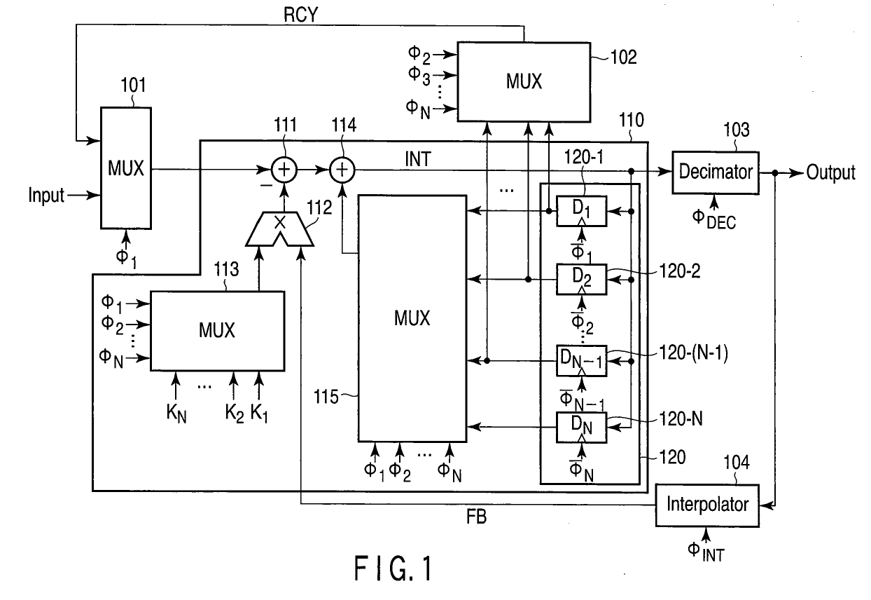

As shown in FIG. 1, a sample rate converter according to a first embodiment of the present invention includes a multiplexer 101, a multiplexer 102, a decimator 103, an interpolator 104, and a loop filter 110. The loop filter 110 is an Nth-order sinc filter (N is a natural number of at least 2) that removes the folding noise. The loop filter 110 includes a subtractor 111, a multiplier 112, a multiplexer 113, an adder 114, a multiplexer 115, and a register circuit 120.

The multiplexer 101 selects one of an input signal Input to the sample rate converter in FIG. 1 and a recycle signal RCY from the multiplexer 102, described below. The multiplexer 101 inputs the selected signal to the subtractor 111 as a selected input signal. The recycle signal RCY is an integration signal having an order lower than N and repeatedly utilized to obtain a final (Nth-order) integration signal INT. The multiplexer 101 is controlled by a control clock Φ1 described below. The control clock Φ1 of “1” allows the input signal Input to be selected, and the control signal Φ1 of “0” allows the recycle signal RCY to be selected.

The multiplier 112 multiplies a feedback signal FB from the interpolator 104, described below, by a selected multiplier coefficient from the multiplexer 113, described below. The multiplier 112 then inputs the result of the multiplication (multiplication signal) to the subtractor 111.

N multiplier coefficients K1, K2, . . . , KN are input to the multiplexer 113, which is controlled by the N control clocks Φ1, Φ2, . . . , ΦN; the same sample rate as that for the input signal Input is used for the N control clocks Φ1, Φ2, . . . , ΦN, and a period of each control clock during which the control clock is “1” does not overlap a period of any other control clock during which the control clock is “1”. The N control clocks Φ1, Φ2, . . . , ΦN are obtained, for example, by shifting, by 2π/N, the phase of each of the clocks for which the period during which the clock is “1” is equal to or shorter than the above-described one cycle multiplied by 1/N. If any one of the control clocks is “1”, the multiplexer 113 selects a corresponding one of the multiplier coefficients and inputs the selected multiplier coefficient to the multiplier 112. Specifically, each of the N control clocks Φ1, Φ2, . . . , ΦN corresponds to each of the N multiplier coefficients K1, K2, . . . , KN on a one-to-one basis. The multiplexer 113 selects one of the multiplier coefficients for each control clock. Each of the multiplier coefficients K1, K2, . . . KN is determined by the down-sample rate (decimation rate) D of the sample rate converter in FIG. 1 and the order N of the loop filter 110. FIG. 5 shows an example of the multiplier coefficients K1, K2, . . . , KN.

The subtractor 111 subtracts the multiplication result from the multiplier 112 from the selected input signal from the multiplexer 101. That is, the subtractor 111 subtracts the feedback signal FB multiplied by the selected multiplier coefficient by the multiplier 111, from the selected input signal. The subtractor 111 inputs the result of the subtraction (residual signal) to the adder 114 as an integrator input signal.

The adder 114 adds the integrator input signal from the subtractor 111 to an integrator feedback signal from the multiplexer 115, described below, for integration. The adder 114 inputs the result of the addition to a register circuit 120 and a decimator 103 as an integration signal INT.

The register circuit 120 includes a flip flop 120-1 that temporarily holds a 1st-order integration signal INT, a flip flop 120-2 that temporarily holds a 2nd-order integration signal INT, . . . , and a flip flop 120-N that temporarily holds an Nth-order integration signal INT. Specifically, the flip flop 120-1 is what is called a positive edge triggered D flip flop controlled by an inversion clock /Φ1 (in the description below, a slash (/) is used to denote the inversion clock) of the control clock Φ1. At a rising edge of the inversion clock /Φ1, the flip flop 120-1 shifts to a latch state to hold the input signal, and then outputs the signal until the next rising edge. On the other hand, the flip flop 120-2, . . . , the flip flop 120-N are controlled by the inversion clocks /Φ2, . . . , /ΦN of the control clocks Φ2, . . . , ΦN, respectively. In the description below, the term flip flop refers to the positive edge triggered D flip flop unless otherwise specified.

The integration signal INT from the adder 114 is input to each of the flip flops 120-1 to 120-N. At the rise of the inversion clock /Φ1, the 1st-order integration signal INT is input to the register circuit 120. The flip flop 120-1 holds the integration signal INT. The flip flop 120-1 inputs the integration signal INT to the multiplexers 102 and 115 until the next rising edge of the inversion clock /Φ1. At the rise of the inversion clock /Φ2, the 2nd-order integration signal INT is input to the register circuit 120. The flip flop 120-2 holds the integration signal INT. The flip flop 120-2 inputs the integration signal INT to the multiplexers 102 and 115 until the next rising edge of the inversion clock /Φ2. At the rise of the inversion clock /ΦN, the Nth-order integration signal INT is input to the register circuit 120. The flip flop 120-N holds the integration signal INT. The flip flop 120-N inputs the integration signal INT only to the multiplexer 115 until the next rising edge of the inversion clock /ΦN.

That is, the flip flops 120-1, 120-2, . . . , 120-(N−1) hold and input the 1st-, 2nd-, . . . , (N−1)th-order integration signals INT to the multiplexers 102 and 115. On the other hand, the flip flop 120-N holds and inputs the Nth-order integration signal INT only to the multiplexer 115. As described below, the Nth-order integration signal INT is not used as a recycle signal RCY and thus need not be input to the multiplexer 102.

The 1st- to Nth-order integration signals INT from the flip flops 120-1 to 120-N in the register circuit 120 are each input to the multiplexer 115. The multiplexer 115 inputs one of the integration signals INT to the adder 114 as an integrator feedback signal. Specifically, the multiplexer 115 is controlled by the control clocks Φ1 to ΦN to select one of the integration signals INT which corresponds to the preceding cycle and which offers an order greater than that of the selected input signal by one.

The decimator 103 is a flip flop controlled by a control clock ΦDEC and operates as a decimator with a down-sample rate D corresponding to the sample rate converter in FIG. 1. That is, the decimator 103 performs decimation such that the number of samples of the integration signal INT from the adder 114 is reduced to 1/D. The decimator 103 outputs the result of the decimation as the output signal Output from the sample rate converter in FIG. 1. The decimator 103 further inputs the decimation result to the interpolator 104.

The interpolator 104 is controlled by the control clock ΦINT to perform interpolation to insert “0”s so that the number of samples in the decimation result from the decimator 103 is increased by a factor of D. Specifically, the interpolator 104 performs an AND operation on the decimation result and the control clock ΦINT. The interpolator 104 inputs the result of the interpolation to the multiplier 112 as the feedback signal FB.

The 1st- to (N−1)th-order integration signals INT from the flip flops 120-1 to 120-(N−1) in the register circuit 120 are each input to the multiplexer 102. The multiplexer 102 then selects any one of the integration signals INT as the recycle signal RCY, and inputs the recycle signal RCY to the multiplexer 101. Specifically, the multiplexer 102 is controlled by the control clocks Φ2 to ΦN to select the 1st- to (N−1)th-order integration signals INT for the respective control clocks. That is, the multiplexer 102 selects the 1st-order integration signal INT for the control clock Φ2, the 2nd-order integration signal INT for the control clock Φ3, . . . , and the (N−1)th-order integration signal INT for the control clock ΦN. While all of the control clocks Φ2 to ΦN are “0” (for example, while the control clock Φ1 is “1”), the multiplexer 102 may be in a floating state (Z).

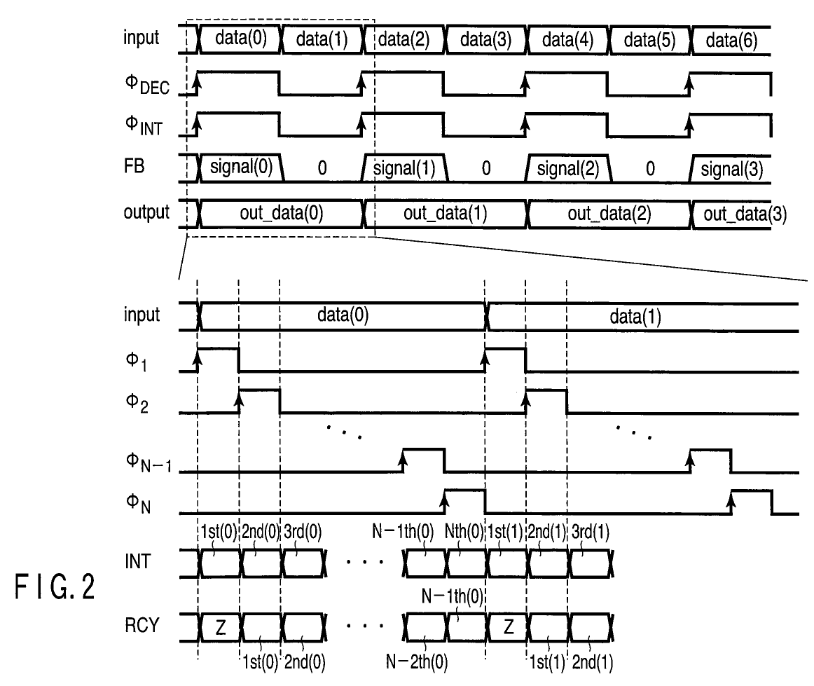

Now, operations of the sample rate converter in FIG. 1 will be described with reference to a timing chart in FIG. 2. In the description below, the down-sample rate D of the sample rate converter is “2”. A lower stage in FIG. 2 shows the timing chart of a specified region in an upper stage of FIG. 2 in further detail.

As shown in the lower stage in FIG. 2, the same sample rate as that for the input signal Input is used for the control clocks Φ1 to ΦN. The phase of each of the control clocks Φ1 to ΦN differs from that of the succeeding control clock by 2π/N. First, at the rise of the control clock Φ1, the multiplexer 101 selects and inputs the input signal Input (=data(0)) to the subtractor 111.

The multiplier 112 multiplies the feedback signal FB (=signal(0)) from the interpolator 104 by the selected multiplier coefficient from the multiplexer 113. Here, since the control clock Φ1 is “1”, the multiplexer 113 selects the multiplier coefficient K1 as a selected multiplier coefficient and inputs the selected multiplier coefficient to the multiplier 112. The multiplier 112 then inputs the result of the multiplication (=K1*signal(0)) to the subtractor 111.

The subtractor 111 subtracts the multiplication result (=K1*signal(0)) from the selected input signal (=data(0)) from the multiplexer 101. The subtractor 111 inputs the result of the subtraction (=data(0)−K1*signal(0)) to the adder 114 as an integrator input signal. Since the control clock Φ1 is “1”, the multiplexer 115 inputs the 1st-order integration signal INT (=0) corresponding to the preceding cycle, to the adder 114 as an integrator feedback signal.

The adder 114 adds the integrator feedback signal (=0) from the multiplexer 115 to the integrator input signal (=data(0)−K1*signal(0)) from the subtractor 111. The adder 114 inputs the result of the addition to the register circuit 120 and the decimator 103 as the 1st-order integration signal INT (=data (0)−K1*signal(0)=1st(0)). The flip flop 120-1 in the register circuit 120 holds the 1st-order integration signal INT (=1st(0)) from the adder 114 at the fall of the control clock Φ1 (at the rise of the inversion clock /Φ1).

Then, the control clock Φ2 rises. Since the control clock Φ2 is “1”, the multiplexer 102 selects the 1st-order integration signal INT (=1st(0)) from the flip flop 120-1 in the register circuit 120 as the recycle signal RCY. The multiplexer 102 inputs the recycle signal RCY to the multiplexer 101.

Since the control clock Φ1 is “0”, the multiplexer 101 selects the recycle signal RCY (=1st(0)) from the multiplexer 102 and inputs the selected input signal to the subtractor 111.

The multiplier 112 multiples the feedback signal FB (=signal(0)) from the interpolator 104 by the selected multiplier coefficient from the multiplexer 113. Here, since the control clock Φ2 is “1”, the multiplexer 113 selects the multiplier coefficient K2 and inputs the selected multiplier coefficient to the multiplier 112. The multiplier 112 inputs a result of multiplication (=K2*signal(0)) to the subtractor 111.

The subtractor 111 subtracts the multiplication result (=K2*signal(0)) from the multiplier 112, from the selected input signal (=1st(0)) from the multiplexer 101. The subtractor 111 then inputs the result of the subtraction (=1st(0)−K2*signal(0)) to the adder 114 as an integrator input signal. Since the control clock Φ2 is “1”, the multiplexer 115 inputs the 2nd-order integration signal INT (=0) corresponding to the preceding cycle, to the adder 114 as an integrator feedback signal.

The adder 114 adds the integrator feedback signal (=0) from the multiplexer 115 to the integrator input signal (=1st(0)−K2*signal(0)) from the subtractor 111. The adder 114 then inputs the result of the addition to the register circuit 120 and the decimator 103 as the 2nd-order integration signal INT (=1st(0)−K2*signal(0)=2nd(0)). At the fall of the control clock (at the rise of the inversion clock /Φ2), the flip flop 120-2 in the register circuit 120 holds the 2nd-order integration signal INT (=2nd (0)) from the adder 114.

Thereafter, the sample rate converter in FIG. 1 repeats similar operations from the rise of the control clock Φ3 until the fall of the control clock ΦN−1, and the description of this period is thus omitted.

When the control clock ΦN rises, the multiplexer 102 selects the (N−1)th-order integration signal INT (=(N−1)th(0)) from the flip flop 120-(N−1) in the register circuit 120 as the recycle signal RCY. The multiplexer 102 inputs the recycle signal RCY to the multiplexer 101.

Since the control clock Φ1 is “0”, the multiplexer 101 selects the recycle signal RCY (=(N−1)th(0)) from the multiplexer 102, and inputs the recycle signal RCY to the subtractor 111.

The multiplier 112 multiples the feedback signal FB (=signal(0)) from the interpolator 104 by the selected multiplier coefficient from the multiplexer 113. Here, since the control clock ΦN is “1”, the multiplexer 113 selects the multiplier coefficient KN and inputs the selected multiplier coefficient to the multiplier 112. The multiplier 112 inputs a result of multiplication (=KN*signal(0)) to the subtractor 111.

The subtractor 111 subtracts the multiplication result (=KN*signal(0)) from the multiplier 112, from the selected input signal (=(N−1)th(0)) from the multiplexer 101. The subtractor 111 then inputs the result of the subtraction (=(N−1)th(0)−KN*signal (0)) to the adder 114 as an integrator input signal. Since the control clock ΦN is “1”, the multiplexer 115 inputs the Nth-order integration signal INT (=0) corresponding to the preceding cycle, to the adder 114 as an integrator feedback signal.

The adder 114 adds the integrator feedback signal (=0) from the multiplexer 115 to the integrator input signal (=(N−1)th(0)−KN*signal(0)) from the subtractor 111. The adder 114 then inputs the result of the addition to the register circuit 120 and the decimator 103 as the Nth-order integration signal INT (=(N−1)th(0)−KN*signal(0)=Nth(0)). At the fall of the control clock ΦN (at the rise of the inversion clock /ΦN), the flip flop 120-N in the register circuit 120 holds the Nth-order integration signal INT (=Nth(0)) from the adder 114.

Then, when the control clock Φ1 rises again, the multiplexer 101 selects the input signal Input (=data (1)), and inputs the selected input signal to the subtractor 111.

The multiplier 112 multiples the feedback signal FB (=0) from the interpolator 104 by the selected multiplier coefficient from the multiplexer 113. Here, since the control clock Φ1 is “1”, the multiplexer 113 selects the multiplier coefficient K1 and inputs the selected multiplier coefficient to the multiplier 112. The multiplier 112 inputs a result of multiplication (=0) to the subtractor 111.

The subtractor 111 subtracts the multiplication result (=0) from the multiplier 112, from the selected input signal (=data(1)) from the multiplexer 101. The subtractor 111 then inputs the result of the subtraction (=data(1)) to the adder 114 as an integrator input signal. Since the control clock Φ1 is “1”, the multiplexer 115 inputs the 1st-order integration signal INT (=1st(0)) corresponding to the preceding cycle, to the adder 114 as an integrator feedback signal.

The adder 114 adds the integrator feedback signal (=1st(0)) from the multiplexer 115 to the integrator input signal (=data(1)) from the subtractor 111. The adder 114 then inputs the result of the addition to the register circuit 120 and the decimator 103 as the 1st-order integration signal INT (=data(1)+1st (0)=1st(1)). At the rise of the inversion clock /ΦD, the flip flop 120-1 in the register circuit 120 holds the 1st-order integration signal INT (=1st (1)) from the adder 114.

Then, the control clock Φ2 rises. Since the control clock Φ2 is “1”, the multiplexer 102 selects the 1st-order integration signal INT (=1st(1)) from the flip flop 120-1 in the register circuit 120 as the recycle signal RCY. The multiplexer 102 inputs the recycle signal RCY to the multiplexer 101.

Since the control clock Φ1 is “0”, the multiplexer 101 selects the recycle signal RCY (=1st(1)) from the multiplexer 102 and inputs the selected input signal to the subtractor 111.

The multiplier 112 multiples the feedback signal FB (=0) from the interpolator 104 by the selected multiplier coefficient from the multiplexer 113. Here, since the control clock Φ2 is “1”, the multiplexer 113 selects the multiplier coefficient K2 and inputs the selected multiplier coefficient to the multiplier 112. The multiplier 112 inputs a result of multiplication (=0) to the subtractor 111.

The subtractor 111 subtracts the multiplication result (=0) from the multiplier 112, from the selected input signal (=1st(1)) from the multiplexer 101. The subtractor 111 then inputs the result of the subtraction (=1st(1)) to the adder 114 as an integrator input signal. Since the control clock Φ2 is “1”, the multiplexer 115 inputs the 2nd-order integration signal INT (=2nd(0)) corresponding to the preceding cycle, to the adder 114 as an integrator feedback signal.

The adder 114 adds the integrator feedback signal (=2nd(0)) from the multiplexer 115 to the integrator input signal (=1st(1)) from the subtractor 111. The adder 114 then inputs the result of the addition to the register circuit 120 and the decimator 103 as the 2nd-order integration signal INT (=1st(1)+2nd (0)=2nd(1)). At the rise of the inversion clock /Φ2, the flip flop 120-2 in the register circuit 120 holds the 2nd-order integration signal INT (=2nd (1)) from the adder 114.

Thereafter, the sample rate converter in FIG. 1 repeats similar operations from the rise of the control clock Φ3 until the fall of the control clock ΦN−1, and the description of this period is thus omitted.

When the control clock ΦN rises, the multiplexer 102 selects the (N−1)th-order integration signal INT (=(N−1)th(1)) from the flip flop 120-(N−1) in the register circuit 120 as the recycle signal RCY. The multiplexer 102 inputs the recycle signal RCY to the multiplexer 101.

Since the control clock Φ1 is “0”, the multiplexer 102 selects the recycle signal RCY (=(N−1)th(1)) from the multiplexer 102, and inputs the recycle signal RCY to the subtractor 101.

The multiplier 112 multiples the feedback signal FB (=0) from the interpolator 104 by the selected multiplier coefficient from the multiplexer 113. Here, since the control clock ΦN is “1”, the multiplexer 113 selects the multiplier coefficient KN and inputs the selected multiplier coefficient to the multiplier 112. The multiplier 112 inputs a result of multiplication (=0) to the subtractor 111.

The subtractor 111 subtracts the multiplication result (=0) from the multiplier 112, from the selected input signal (=(N−1)th(1)) from the multiplexer 101. The subtractor 111 then inputs the result of the subtraction (=(N−1)th(1)) to the adder 114 as an integrator input signal. Since the control clock ΦN is “1”, the multiplexer 115 inputs the Nth-order integration signal INT (=Nth(0)) corresponding to the preceding cycle, to the adder 114 as a first integrator feedback signal.

The adder 114 adds the integrator feedback signal (=Nth(0)) from the multiplexer 115 to the integrator input signal (=(N−1)th(1)) from the subtractor 111. The adder 114 then inputs the result of the addition to the register circuit 120 and the decimator 103 as the Nth-order integration signal INT (=(N−1)th(1)+Nth (0)=Nth(1)). At the rise of the inversion clock /ΦN, the flip flop 120-N in the register circuit 120 holds the Nth-order integration signal INT (=Nth (1)) from the adder 114. At the rise of the control clock ΦDEC, the decimator 103 holds and outputs the Nth-order integration signal INT (=Nth(1)) as an output signal Output (=out_data(1)).

As described above, the sample rate converter in FIG. 1 performs the Nth-order integration on the input signal to suppress the folding noise before down-sampling. Specifically, the sample rate converter in FIG. 1 repeatedly utilizes the single integration circuit composed of the subtractor 111, the multiplier 112, and the adder 114, N times to carry out signal processing similar to that carried out by a circuit with N cascaded integration circuits. Specifically, to, perform a Jth-order (J is a natural number of at least 2 and at most N) integration, the multiplexer 102 selects a (J−1)th integration signal as the recycle signal RCY. Then, the multiplexer 101 selects the recycle signal RCY as a selected input signal. Furthermore, the multiplexer 115 selects the Jth-order integration signal corresponding to the preceding cycle, as an integrator feedback signal. The adder 114 then performs the Jth-order integration.

As described above, the sample rate converter according to the present embodiment repeatedly utilizes the single-stage loop filter N times to fulfill a noise suppression capability equivalent to that of an N-th order loop filter. Therefore, the sample rate converter according to the present embodiment inhibits an increase in circuit area resulting from the increased order of the loop filter.

### Second Embodiment

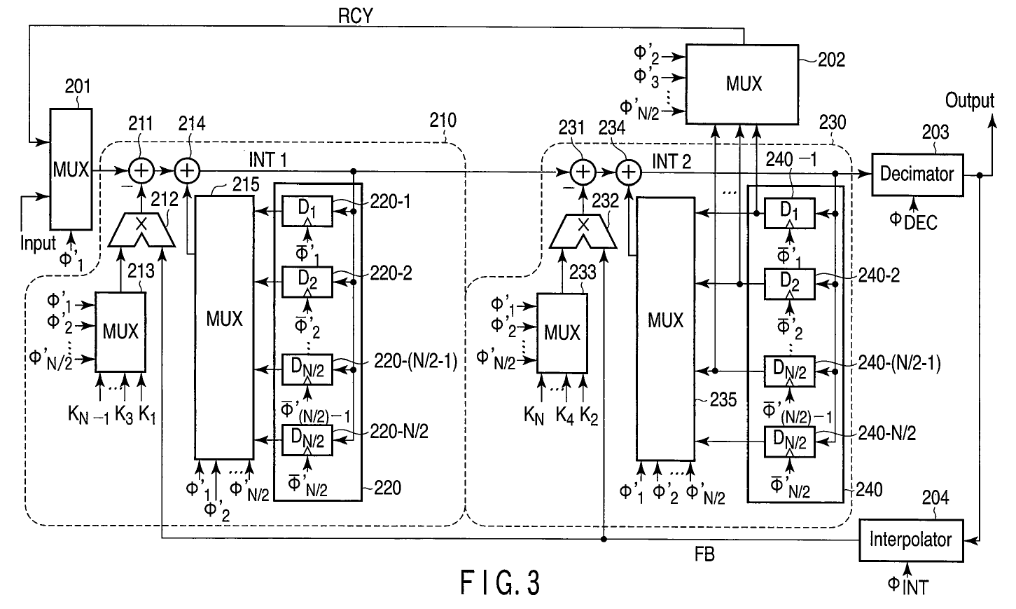

As shown in FIG. 3, a sample rate converter according to a second embodiment of the present invention includes a multiplexer 201, a multiplexer 202, a decimator 203, an interpolator 204, a loop filter 210, and a loop filter 230. Each of the loop filters 210 and 230 is an N/2th-order sinc filter (N is an even number of at least 4) that suppresses the folding noise. The loop filter 210 includes a subtractor 211, a multiplexer 212, a multiplexer 213, an adder 214, a multiplexer 215, and a register circuit 220. The loop filter 230 includes a subtractor 231, a multiplexer 232, a multiplexer 233, an adder 234, a multiplexer 235, and a register circuit 240.

The multiplexer 201 selects one of the input signal Input to the sample rate converter in FIG. 3 and the recycle signal RCY from the multiplexer 202, described below. The multiplexer 201 inputs the selected signal to the subtractor 211 as a selected input signal. The recycle signal RCY is an integration signal having an even number order lower than N and repeatedly utilized to obtain a final (Nth-order) integration signal INT2. The multiplexer 201 is controlled by a control clock Φ′1 described below. The control clock Φ′1 of “1” allows the input signal Input to be selected, and the control signal Φ′1 of “0” allows the recycle signal RCY to be selected.

The multiplier 212 multiplies the feedback signal FB from the interpolator 204, described below, by the selected multiplier coefficient from the multiplexer 213, described below. The multiplier 212 then inputs the result of the multiplication to the subtractor 211.

N/2 multiplier coefficients K1, K3, . . . , KN−1 are input to the multiplexer 213, which is controlled by the N/2 control clocks Φ′1, Φ′2, . . . , Φ′N/2; the same sample rate as that for the input signal Input is used for the N/2 control clocks Φ′1, Φ′2, . . . , Φ′N/2, and a period of each control clock during which the control clock is “1” does not overlap a period of any other control clock during which the control clock is “1”. The N control clocks Φ′l, Φ′2, . . . , Φ′N/2 are obtained, for example, by shifting, by 4π/N, the phase of each of the clocks for which the period during which the clock is “1” is equal to or shorter than the above-described one cycle multiplied by 2/N. If any one of the control clocks is “1”, the multiplexer 213 selects a corresponding one of the multiplier coefficients and inputs the selected multiplier coefficient to the multiplier 212. Specifically, each of the N/2 control clocks Φ′1, Φ′2, . . . , Φ′N/2 corresponds to each of the N/2 multiplier coefficients K1, K3, . . . , KN−1 on a one-to-one basis. The multiplexer 213 selects one of the multiplier coefficients for each control clock. The multiplier coefficients K1, K3, . . . KN−1 are odd number-order coefficients of the multiplier coefficients K1, K2, . . . KN according to the first embodiment, described above. That is, the multiplier coefficients K1, K3, . . . , KN−1 are required for odd number-order integrations.

The subtractor 211 subtracts the multiplication result from the multiplier 212 from the selected input signal from the multiplexer 201. That is, the subtractor 211 subtracts the feedback signal FB multiplied by the selected multiplier coefficient by the multiplier 212, from the selected input signal. The subtractor 211 inputs the result of the subtraction (residual signal) to the adder 214 as a first integrator input signal.

The adder 214 adds the integrator input signal from the subtractor 211 to a first integrator feedback signal from the multiplexer 215, described below, for integration. The adder 214 inputs the result of the addition to the register circuit 220 and the subtractor 231 as an integration signal INT1.

The register circuit 220 includes a flip flop 220-1 that temporarily holds a 1st-order integration signal INT1, a flip flop 220-2 that temporarily holds a 3rd-order integration signal INT1, . . . , and a flip flop 220-N/2 that temporarily holds an (N−1)th-order integration signal INT1. That is, the register circuit 220 temporarily holds each of the odd number-order integration signals INT1.

The flip flop 220-1 is controlled by an inversion clock /Φ′1 of the control clock Φ′1. At a rising edge of the inversion clock /Φ′1, the flip flop 220-1 shifts to the latch state to hold the input signal, and then outputs the signal until the next rising edge. On the other hand, the flip flop 220-2, . . . , the flip flop 220-N/2 are controlled by the inversion clocks /Φ′2, . . . , /Φ′N/2 of the control clocks Φ′2, . . . , Φ′N/2, respectively.

The integration signal INT1 from the adder 214 is input to each of the flip flops 220-1 to 220-N/2. At the rise of the inversion clock /Φ′1, the 1st-order integration signal INT1 is input to the register circuit 220. The flip flop 220-1 holds the integration signal INT1. The flip flop 220-1 inputs the integration signal INT1 to the multiplexer 215 until the next rising edge of the inversion clock /Φ′1. At the rise of the inversion clock /Φ′2, the 3rd-order integration signal INT1 is input to the register circuit 220. The flip flop 220-2 holds the integration signal INT1. The flip flop 220-2 inputs the integration signal INT1 to the multiplexer 215 until the next rising edge of the inversion clock /Φ′2. At the rise of the inversion clock /Φ′N/2, the (N−1)th-order integration signal INT1 is input to the register circuit 220. The flip flop 220-N/2 holds the integration signal INT1. The flip flop 220-N/2 inputs the integration signal INT1 to the multiplexer 215 until the next rising edge of the inversion clock /Φ′N/2.

That is, the flip flops 220-1, 220-2, . . . , 220-N/2 hold and input the 1st-, 3rd-, . . . , (N−1)th-order integration signals INT1 to the multiplexer 215.

The 1st- to (N−1)th-order integration signals INT1 from the flip flops 220-1 to 220-N/2 in the register circuit 220 are each input to the multiplexer 215. The multiplexer 215 inputs one of the integration signals INT1 to the adder 214 as an integrator feedback signal. Specifically, the multiplexer 215 is controlled by the control clocks Φ′1 to Φ′N/2 to select, as a first integrator feedback signal, one of the integration signals INT1 which corresponds to the preceding cycle and which offers an order greater than that of the selected input signal by one.

The multiplier 232 multiplies the feedback signal FB from the interpolator 204, described below, by a selected multiplier coefficient from the multiplexer 233, described below. The multiplier 232 then inputs the result of the multiplication to the subtractor 231.

N/2 multiplier coefficients K2, K4, . . . , KN are input to the multiplexer 233, which is controlled by the N/2 control clocks Φ′1, Φ′2, . . . , Φ′N/2. If any one of the control clocks is “1”, the multiplexer 223 selects a corresponding one of the multiplier coefficients and inputs the selected multiplier coefficient to the multiplier 232. Specifically, each of the N/2 control clocks Φ′1, Φ′2, . . . , Φ′N/2 corresponds to each of the N/2 multiplier coefficients K2, K4, . . . , KN on a one-to-one basis. The multiplexer 233 selects one of the multiplier coefficients for each control clock. The multiplier coefficients K2, K4, . . . KN are even number-order coefficients of the multiplier coefficients K1, K2, . . . , KN according to the first embodiment. That is, the multiplier coefficients K1, K2, . . . , KN are required for even number-order integrations.

The subtractor 231 subtracts the multiplication result from the multiplier 232 from the integration signal INT1 from the adder 214. That is, the subtractor 231 subtracts the feedback signal FB multiplied by the selected multiplier coefficient by the multiplier 232, from the integration signal INT1. The subtractor 231 inputs the result of the subtraction to the adder 234 as a second integrator input signal.

The adder 234 adds the integrator input signal from the subtractor 231 to a second integrator feedback signal from the multiplexer 235, described below, for integration. The adder 234 inputs the result of the addition to the register circuit 240 and the decimator 203 as an integration signal INT2.

The register circuit 240 includes a flip flop 240-1 that temporarily holds a 2nd-order integration signal INT2, a flip flop 240-2 that temporarily holds a 4th-order integration signal INT2, . . . , and a flip flop 240-N/2 that temporarily holds an Nth-order integration signal INT2. That is, the register circuit 240 temporarily holds each of the even number-order integration signals INT2.

The flip flop 240-1 is controlled by an inversion clock /Φ′1. At a rising edge of the inversion clock /Φ′l, the flip flop 240-1 shifts to the latch state to hold the input signal, and then outputs the signal until the next rising edge. On the other hand, the flip flop 240-2, . . . , the flip flop 240-N/2 are controlled by the inversion clocks /Φ′2, . . . , /Φ′N/2, respectively.

The integration signal INT2 from the adder 234 is input to each of the flip flops 240-1 to 240-N/2. At the rise of the inversion clock /Φ′1, the 2nd-order integration signal INT2 is input to the register circuit 240. The flip flop 240-1 holds the integration signal INT2. The flip flop 240-1 inputs the integration signal INT2 to the multiplexers 202 and 235 until the next rising edge of the inversion clock /Φ′1. At the rise of the inversion clock /Φ′2, the 4th-order integration signal INT2 is input to the register circuit 240. The flip flop 240-2 holds the integration signal INT2. The flip flop 240-2 inputs the integration signal INT2 to the multiplexers 202 and 235 until the next rising edge of the inversion clock /Φ′2. At the rise of the inversion clock /Φ′N/2, the Nth-order integration signal INT2 is input to the register circuit 240. The flip flop 240-N/2 holds the integration signal INT2. The flip flop 240-N/2 inputs the integration signal INT2 only to the multiplexer 235 until the next rising edge of the inversion clock /Φ′N/2.

That is, the flip flops 240-1, 240-2, . . . , 240-(N/2−1) hold and input the 2nd-, 4th-, . . . , (N−2)th-order integration signals INT2 to the multiplexers 202 and 235. On the other hand, the flip flop 240-N/2 holds and inputs the Nth-order integration signal INT2 only to the multiplexer 235. As described above, the Nth-order integration signal INT2 is not used as the recycle signal RCY and thus need not be input to the multiplexer 202.

The 2nd- to Nth-order integration signals INT2 from the flip flops 240-1 to 240-N/2 in the register circuit 240 are each input to the multiplexer 235. The multiplexer 235 inputs one of the integration signals INT2 to the adder 234 as a second integrator feedback signal. Specifically, the multiplexer 235 is controlled by the control clocks Φ′1 to Φ′N/2 to select, as a second integrator feedback signal, one of the integration signals INT2 which corresponds to the preceding cycle and which offers an order greater than that of the integration signal INT1 input to the subtractor 231, by one.

The decimator 203 is a flip flop controlled by a control clock ΦDEC and operates as a decimator with the down-sample rate D corresponding to the sample rate converter in FIG. 3. That is, the decimator 203 performs decimation such that the number of samples of the integration signal INT2 from the adder 234 is reduced to 1/D. The decimator 203 outputs the result of the decimation as the output signal Output from the sample rate converter in FIG. 3. The decimator 203 further inputs the decimation result to the interpolator 204.

The interpolator 204 is controlled by the control clock ΦINT to perform interpolation to insert “0”s so that the number of samples in the decimation result from the decimator 203 is increased by a factor of D. Specifically, the interpolator 204 performs an AND operation on the decimation result and the control clock ΦINT. The interpolator 204 inputs the result of the interpolation to the multipliers 212 and 232 as the feedback signal FB.

The 2nd- to (N−2)th-order integration signals INT2 from the flip flops 240-1 to 240-(N−1) in the register circuit 240 are each input to the multiplexer 202. The multiplexer 202 then selects any one of the integration signals INT as the recycle signal RCY, and inputs the recycle signal RCY to the multiplexer 201. Specifically, the multiplexer 202 is controlled by the control clocks Φ′2 to Φ′N/2 to select the 2nd- to (N−2)th-order integration signals INT2 for the respective control clocks. That is, the multiplexer 202 selects the 2nd-order integration signal INT2 for the control clock Φ′2, the 4th-order integration signal INT2 for the control clock Φ′3, . . . , and the (N−2)th-order integration signal INT2 for the control clock Φ′N/2. While all of the control clocks Φ′2 to Φ′N/2 are “0” (for example, while the control clock Φ′1 is “1”), the multiplexer 202 may be in the floating state (Z).

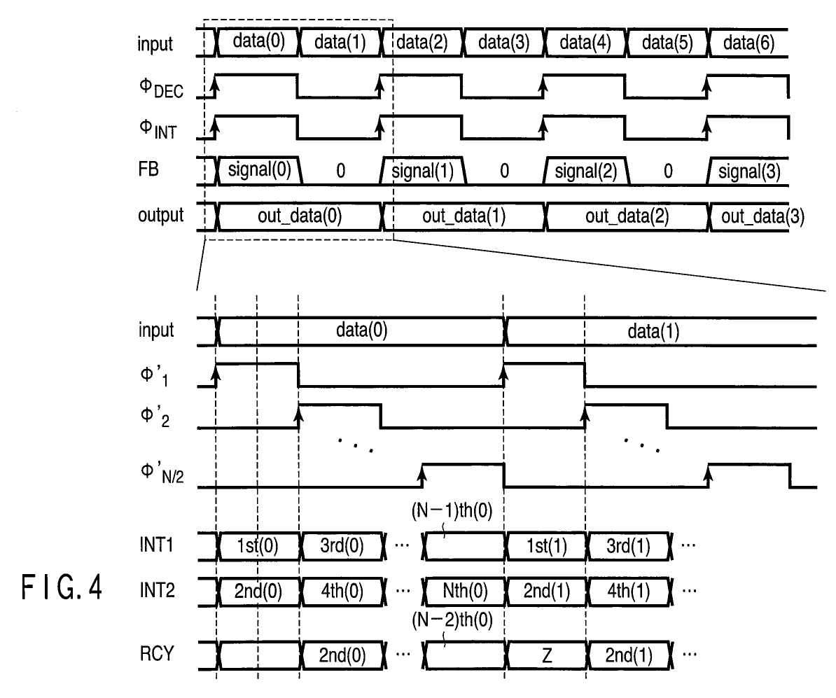

Now, operations of the sample rate converter in FIG. 3 will be described with reference to a timing chart in FIG. 4. In the description below, the down-sample rate D of the sample rate converter is “2”. A lower stage in FIG. 4 shows the timing chart of a specified region in an upper stage of FIG. 4 in further detail.

As shown in the lower stage in FIG. 4, the same sample rate as that for the input signal Input is used for the control clocks Φ′1 to Φ′N/2. The phase of each of the control clocks Φ′1 to Φ′N/2 differs from that of the succeeding control clock by 4π/N. First, at the rise of the control clock Φ′1, the multiplexer 201 selects and inputs the input signal Input (=data (0)) to the subtractor 211.

The multiplier 212 multiplies the feedback signal FB (=signal(0)) from the interpolator 204 by the selected multiplier coefficient from the multiplexer 213. Here, since the control clock Φ′1 is “1”, the multiplexer 213 selects the multiplier coefficient K1 as a selected multiplier coefficient and inputs the selected multiplier coefficient to the multiplier 212. The multiplier 212 then inputs the result of the multiplication (=K1*signal(0)) to the subtractor 211.

The subtractor 211 subtracts the multiplication result (=K1*signal(0)) from the multiplier 212, from the selected input signal (=data(0)) from the multiplexer 201. The subtractor 211 inputs the result of the subtraction (=data(0)−K1*signal(0)) to the adder 214 as an integrator input signal. Since the control clock Φ′1 is “1”, the multiplexer 215 inputs the 1st-order integration signal INT1 (0) corresponding to the preceding cycle, to the adder 214 as a first integrator feedback signal.

The adder 214 adds the first integrator feedback signal (=0) from the multiplexer 215 to the first integrator input signal (=data(0)−K1*signal(0)) from the subtractor 211. The adder 214 inputs the result of the addition to the register circuit 220 and the subtractor 231 as the 1st-order integration signal INT1 (=data(0)−K1*signal(0)=1st(0)). The flip flop 220-1 in the register circuit 220 holds the 1st-order integration signal INT1 (=1st(0)) from the adder 214 at the fall of the control clock Φ′1 (at the rise of the inversion clock /Φ′1).

The multiplier 232 multiplies the feedback signal FB (=signal(0)) from the interpolator 204 by the selected multiplier coefficient from the multiplexer 233. Here, since the control clock Φ1 is “1”, the multiplexer 233 selects the multiplier coefficient K2 as a selected multiplier coefficient and inputs the selected multiplier coefficient to the multiplier 232. The multiplier 232 then inputs the result of the multiplication (=K2*signal(0)) to the subtractor 231.

The subtractor 231 subtracts the multiplication result (=K2*signal(0)) from the multiplier 232, from the integration signal INT1 (=1st(0)) from the adder 214. The subtractor 231 inputs the result of the subtraction (=1st(0)−K2*signal(0)) to the adder 234 as a second integrator input signal. Since the control clock Φ′1 is “1”, the multiplexer 235 inputs the 2nd-order integration signal INT2 (0) corresponding to the preceding cycle, to the adder 234 as a second integrator feedback signal.

The adder 234 adds the second integrator feedback signal (=0) from the multiplexer 235 to the second integrator input signal (=1st(0)−K2*signal(0)) from the subtractor 231. The adder 234 inputs the result of the addition to the register circuit 240 and the decimator 203 as the 2nd-order integration signal INT2 (=1st(0)−K2*signal(0)=2nd(0)). The flip flop 240-1 in the register circuit 240 holds the 2nd-order integration signal INT2 (=2nd(0)) from the adder 234 at the rise of the inversion clock /Φ′1.

Then, the control clock Φ′2 rises. Since the control clock Φ′2 is “1”, the multiplexer 202 selects the 2nd-order integration signal INT2 (=2nd (0)) from the flip flop 240-1 in the register circuit 240 as the recycle signal RCY. The multiplexer 202 inputs the recycle signal RCY to the multiplexer 201.

Since the control clock Φ′1 is “0”, the multiplexer 201 selects the recycle signal RCY (=2nd (0)) from the multiplexer 202 and inputs the selected input signal to the subtractor 211.

The multiplier 212 multiples the feedback signal FB (=signal(0)) from the interpolator 204 by the selected multiplier coefficient from the multiplexer 213. Here, since the control clock Φ′2 is “1”, the multiplexer 213 selects the multiplier coefficient K3 and inputs the selected multiplier coefficient to the multiplier 212. The multiplier 212 inputs a result of multiplication (=K3*signal(0)) to the subtractor 211.

The subtractor 211 subtracts the multiplication result (=K3*signal(0)) from the multiplier 212, from the selected input signal (=2nd (0)) from the multiplexer 201. The subtractor 211 then inputs the result of the subtraction (=2nd(0)−K3*signal(0)) to the adder 214 as a first integrator input signal. Since the control clock Φ′2 is “1”, the multiplexer 215 inputs the 3rd-order integration signal INT1 (0) corresponding to the preceding cycle, to the adder 214 as a first integrator feedback signal.

The adder 214 adds the first integrator feedback signal (=0) from the multiplexer 215 to the first integrator input signal (=2nd(0)−K3*signal(0)) from the subtractor 211. The adder 214 then inputs the result of the addition to the register circuit 220 and the subtractor 231 as the 3rd-order integration signal INT1 (=2nd(0)−K3*signal(0)=3rd(0)). At the fall of the control clock Φ′2 (at the rise of the inversion clock /Φ′2), the flip flop 220-2 in the register circuit 220 holds the 3rd-order integration signal INT1 (=3rd(0)) from the adder 214.

The multiplier 232 multiples the feedback signal FB (=signal(0)) from the interpolator 204 by the selected multiplier coefficient from the multiplexer 233. Here, since the control clock Φ′2 is “1”, the multiplexer 233 selects the multiplier coefficient K4 and inputs the selected multiplier coefficient to the multiplier 232. The multiplier 232 inputs a result of multiplication (=K4*signal(0)) to the subtractor 231.

The subtractor 231 subtracts the multiplication result (=K4*signal(0)) from the multiplier 232, from the integration signal INT1 (=3rd(0)) from the adder 214. The subtractor 231 then inputs the result of the subtraction (=3rd(0)−K4*signal(0)) to the adder 234 as a second integrator input signal. Since the control clock Φ′2 is “1”, the multiplexer 235 inputs the 4th-order integration signal INT2 (0) corresponding to the preceding cycle, to the adder 234 as a second integrator feedback signal.

The adder 234 adds the second integrator feedback signal (=0) from the multiplexer 235 to the second integrator input signal (=3rd(0)−K4*signal(0)) from the subtractor 231. The adder 214 then inputs the result of the addition to the register circuit 240 and the decimator 203 as the 4th-order integration signal INT2 (=3rd(0)−K4*signal(0)=4th(0)). At the rise of the inversion clock /Φ′2, the flip flop 240-2 in the register circuit 240 holds the 4th-order integration signal INT2 (=4th(0)) from the adder 234.

Thereafter, the sample rate converter in FIG. 3 repeats similar operations from the rise of the control clock Φ′3 until the fall of the control clock Φ′N/2−1, and the description of this period is thus omitted.

When the control clock Φ′N/2 rises, the multiplexer 202 selects the (N−2)th-order integration signal INT2 (=(N−2)th(0)) from the flip flop 240-(N/2−1) in the register circuit 240 as the recycle signal RCY. The multiplexer 202 inputs the recycle signal RCY to the multiplexer 201.

Since the control clock Φ′1 is “0”, the multiplexer 201 selects the recycle signal RCY (=(N−2)th(0)) from the multiplexer 202, and inputs the recycle signal RCY to the subtractor 211 as a selected input signal.

The multiplier 212 multiples the feedback signal FB (=signal(0)) from the interpolator 204 by the selected multiplier coefficient from the multiplexer 213. Here, since the control clock Φ′N/2 is “1”, the multiplexer 213 selects the multiplier coefficient KN−1 and inputs the selected multiplier coefficient to the multiplier 212. The multiplier 212 inputs a result of multiplication (=KN−1*signal(0)) to the subtractor 211.

The subtractor 211 subtracts the multiplication result (=KN−1*signal(0)) from the multiplier 212, from the selected input signal (=(N−2)th(0)) from the multiplexer 201. The subtractor 211 then inputs the result of the subtraction (=(N−2)th(0)−KN−1* signal(0)) to the adder 214 as a first integrator input signal. Since the control clock D′N/2 is “1”, the multiplexer 215 inputs the (N−1)th-order integration signal INT1 (0) corresponding to the preceding cycle, to the adder 214 as a first integrator feedback signal.

The adder 214 adds the integrator feedback signal (=0) from the multiplexer 215 to the integrator input signal (=(N−2)th(0)−KN−1*signal(0)) from the subtractor 211. The adder 214 then inputs the result of the addition to the register circuit 220 and the subtractor 231 as the (N−1)th-order integration signal INT1 (=(N−2)th(0)−KN−1*signal(0)=(N−1)th(0)). At the fall of the control clock Φ′N/2 (at the rise of the inversion clock /Φ′N/2), the flip flop 220-N/2 in the register circuit 220 holds the (N−1)th-order integration signal INT1 (=(N−1)th(0)) from the adder 214.

The multiplier 232 multiples the feedback signal FB (=signal(0)) from the interpolator 204 by the selected multiplier coefficient from the multiplexer 233. Here, since the control clock Φ′N/2 is “1”, the multiplexer 233 selects the multiplier coefficient KN as a selected multiplier coefficient, and inputs the selected multiplier coefficient to the multiplier 232. The multiplier 232 inputs a result of multiplication (=KN*signal(0)) to the subtractor 231.

The subtractor 231 subtracts the multiplication result (=KN*signal(0)) from the multiplier 232, from the integration signal INT1 (=(N−1)th(0)) from the adder 214. The subtractor 231 then inputs the result of the subtraction (=(N−1)th(0)−KN*signal (0)) to the adder 234 as a second integrator input signal. Since the control clock Φ′N/2 is “1”, the multiplexer 235 inputs the Nth-order integration signal INT2 (0) corresponding to the preceding cycle, to the adder 234 as a second integrator feedback signal.

The adder 234 adds the second integrator feedback signal (=0) from the multiplexer 235 to the second integrator input signal (=(N−1)th(0)−KN*signal (0)) from the subtractor 231. The adder 234 then inputs the result of the addition to the register circuit 240 and the decimator 203 as the Nth-order integration signal INT2 (=(N−1)th(0)−KN*signal (0)=Nth(0)). At the rise of the inversion clock /Φ′N/2, the flip flop 240-N/2 in the register circuit 240 holds the Nth-order integration signal INT2 (=Nth(0)) from the adder 234.

Then, when the control clock Φ′1 rises again, the multiplexer 201 selects the input signal Input (=data (1)), and inputs the selected input signal to the subtractor 211.

The multiplier 212 multiples the feedback signal FB (=0) from the interpolator 204 by the selected multiplier coefficient from the multiplexer 213. Here, since the control clock Φ′1 is “1”, the multiplexer 213 selects the multiplier coefficient K1 as a selected multiplier coefficient, and inputs the selected multiplier coefficient to the multiplier 212. The multiplier 212 inputs a result of multiplication (=0) to the subtractor 211.

The subtractor 211 subtracts the multiplication result (=0) from the multiplier 212, from the selected input signal (=data(1)) from the multiplexer 201. The subtractor 211 then inputs the result of the subtraction (=data(1)) to the adder 214 as a first integrator input signal. Since the control clock Φ′1 is “1”, the multiplexer 215 inputs the 1st-order integration signal INT1 (=1st(0)) corresponding to the preceding cycle, to the adder 214 as a first integrator feedback signal.

The adder 214 adds the first integrator feedback signal (=1st(0)) from the multiplexer 215 to the integrator input signal (=data(1)) from the subtractor 211. The adder 214 then inputs the result of the addition to the register circuit 220 and the subtractor 231 as the 1st-order integration signal INT1 (=data(1)+1st(0)=1st(1)). At the rise of the inversion clock /Φ′1, the flip flop 220-1 in the register circuit 220 holds the 1st-order integration signal INT1 (=1st(1)) from the adder 214.

The multiplier 232 multiples the feedback signal FB (=0) from the interpolator 204 by the selected multiplier coefficient from the multiplexer 233. Here, since the control clock Φ′1 is “1”, the multiplexer 233 selects the multiplier coefficient K2 as a selected multiplier coefficient, and inputs the selected multiplier coefficient to the multiplier 232. The multiplier 232 inputs a result of multiplication (=0) to the subtractor 231.

The subtractor 231 subtracts the multiplication result (=0) from the multiplier 232, from the integration signal INT1 (=1st(1)) from the adder 214. The subtractor 231 then inputs the result of the subtraction (=1st(1)) to the adder 234 as a second integrator input signal. Since the control clock Φ′1 is “1”, the multiplexer 235 inputs the 2nd-order integration signal INT2 (2nd(0)) corresponding to the preceding cycle, to the adder 234 as a second integrator feedback signal.

The adder 234 adds the second integrator feedback signal (=2nd(0)) from the multiplexer 235 to the second integrator input signal (=1st(1)) from the subtractor 231. The adder 234 then inputs the result of the addition to the register circuit 240 and the decimator 203 as the 2nd-order integration signal INT2 (=1st(1)+2nd(0)=2nd(1)). At the rise of the inversion clock /Φ′1, the flip flop 240-1 in the register circuit 240 holds the 2nd-order integration signal INT2 (=2nd(0)) from the adder 234.

Then, the control clock Φ′2 rises. Since the control clock Φ′2 is “1”, the multiplexer 202 selects the 2nd-order integration signal INT2 (=2nd(1)) from the flip flop 240-1 in the register circuit 240 as the recycle signal RCY. The multiplexer 202 inputs the recycle signal RCY to the multiplexer 201.

Since the control clock Φ′1 is “0”, the multiplexer 201 selects the recycle signal RCY (=2nd (1)) from the multiplexer 202 and inputs the selected input signal to the subtractor 211.

The multiplier 212 multiples the feedback signal FB (=(0)) from the interpolator 204 by the selected multiplier coefficient from the multiplexer 213. Here, since the control clock Φ′2 is “1”, the multiplexer 213 selects the multiplier coefficient K3 and inputs the selected multiplier coefficient to the multiplier 212. The multiplier 212 inputs a result of multiplication (=0) to the subtractor 211.

The subtractor 211 subtracts the multiplication result (=0) from the multiplier 212, from the selected input signal (=2nd(1)) from the multiplexer 201. The subtractor 211 then inputs the result of the subtraction (=2nd(1)) to the adder 214 as a first integrator input signal. Since the control clock Φ′2 is “1”, the multiplexer 215 inputs the 3rd-order integration signal INT1 (3rd(0)) corresponding to the preceding cycle, to the adder 214 as a first integrator feedback signal.

The adder 214 adds the first integrator feedback signal (=3rd(0)) from the multiplexer 215 to the first integrator input signal (=2nd(1)) from the subtractor 211. The adder 214 then inputs the result of the addition to the register circuit 220 and the subtractor 231 as the 3rd-order integration signal INT1 (=2nd(1)+3rd(0)=3rd(1)). At the fall of the control clock Φ′2 (at the rise of the inversion clock /Φ′2), the flip flop 220-2 in the register circuit 220 holds the 3rd-order integration signal INT1 (=3rd(1)) from the adder 214.

The multiplier 232 multiples the feedback signal FB (=(0)) from the interpolator 204 by the selected multiplier coefficient from the multiplexer 233. Here, since the control clock Φ′2 is “1”, the multiplexer 233 selects the multiplier coefficient K4 and inputs the selected multiplier coefficient to the multiplier 232. The multiplier 232 inputs a result of multiplication (=0) to the subtractor 231.

The subtractor 231 subtracts the multiplication result (=0) from the multiplier 232, from the integration signal INT1 (=3rd(1)) from the adder 214. The subtractor 231 then inputs the result of the subtraction (=3rd(1)) to the adder 234 as a second integrator input signal. Since the control clock Φ′2 is “1”, the multiplexer 235 inputs the 4th-order integration signal INT2 (4th(0)) corresponding to the preceding cycle, to the adder 234 as a second integrator feedback signal.

The adder 234 adds the second integrator feedback signal (=4th(0)) from the multiplexer 235 to the integrator input signal (=3rd(1)) from the subtractor 231. The adder 234 then inputs the result of the addition to the register circuit 240 and the decimator 203 as the 4th-order integration signal INT2 (=3rd (1)+4th(0)=4th(1)). At the rise of the inversion clock /Φ′2, the flip flop 240-2 in the register circuit 240 holds the 4th-order integration signal INT2 (=4th (1)) from the adder 234.

Thereafter, the sample rate converter in FIG. 3 repeats similar operations from the rise of the control clock Φ′3 until the fall of the control clock Φ′N/2−1, and the description of this period is thus omitted.

When the control clock Φ′N/2 rises, the multiplexer 202 selects the (N−2)th-order integration signal INT2 (=(N−2)th(1)) from the flip flop 240-(N/2−1) in the register circuit 240 as the recycle signal RCY. The multiplexer 202 inputs the recycle signal RCY to the multiplexer 201.

Since the control clock Φ′1 is “0”, the multiplexer 201 selects the recycle signal RCY (=(N−2)th(1)) from the multiplexer 202, and inputs the recycle signal RCY to the multiplexer 202.

The multiplier 212 multiples the feedback signal FB (=0) from the interpolator 204 by the selected multiplier coefficient from the multiplexer 213. Here, since the control clock Φ′N/2 is “1”, the multiplexer 213 selects the multiplier coefficient KN−1 and inputs the selected multiplier coefficient to the multiplier 212. The multiplier 212 inputs a result of multiplication (=0) to the subtractor 211.

The subtractor 211 subtracts the multiplication result (=0) from the multiplier 212, from the selected input signal (=(N−2)th(1)) from the multiplexer 201. The subtractor 211 then inputs the result of the subtraction (=(N−2)th(1)) to the adder 214 as a first integrator input signal. Since the control clock Φ′N/2 is “1”, the multiplexer 215 inputs the (N−1)th-order integration signal INT1 (=(N−1)th(0)) corresponding to the preceding cycle, to the adder 214 as a first integrator feedback signal.

The adder 214 adds the first integrator feedback signal (=(N−1)th(0)) from the multiplexer 215 to the first integrator input signal (=(N−2)th(1)) from the subtractor 211. The adder 214 then inputs the result of the addition to the register circuit 220 and the subtractor 231 as the (N−1)th-order integration signal INT1 (=(N−2)th(1)+(N−1)th(0)=(N−1)th(1)). At the rise of the inversion clock /Φ′N/2, the flip flop 220-N/2 in the register circuit 220 holds the (N−1)th-order integration signal INT1 (=(N−1)th(1)) from the adder 214.

The multiplier 232 multiples the feedback signal FB (=0) from the interpolator 204 by the selected multiplier coefficient from the multiplexer 233. Here, since the control clock Φ′N/2 is “1”, the multiplexer 233 selects the multiplier coefficient KN as a selected multiplier coefficient, and inputs the selected multiplier coefficient to the multiplier 232. The multiplier 232 inputs a result of multiplication (=0) to the subtractor 231.

The subtractor 231 subtracts the multiplication result (=0) from the multiplier 232, from the integration signal INT1 (=(N−1)th(1)) from the adder 214. The subtractor 231 then inputs the result of the subtraction (=(N−1)th(1)) to the adder 234 as a second integrator input signal. Since the control clock Φ′N/2 is “1”, the multiplexer 235 inputs the Nth-order integration signal INT2 (=Nth(0)) corresponding to the preceding cycle, to the adder 234 as a second integrator feedback signal.

The adder 234 adds the second integrator feedback signal (=(N−1)th(0)) from the multiplexer 235 to the second integrator input signal (=(N−1)th(1)) from the subtractor 231. The adder 234 then inputs the result of the addition to the register circuit 240 and the decimator 203 as the Nth-order integration signal INT2 (=(N−1)th(1)+Nth(0)=Nth(1)). At the rise of the inversion clock /Φ′N/2, the flip flop 240-N/2 in the register circuit 240 holds the Nth-order integration signal INT2 (=Nth(1)) from the adder 234. At the rise of the control clock ΦDEC, the decimator 203 holds and outputs the Nth-order integration signal INT2 (=Nth(1)) as the output signal Output (=out_data(1)).

As described above, the sample rate converter in FIG. 3 performs the Nth-order integration on the input signal to suppress the folding noise before down-sampling. Specifically, the sample rate converter in FIG. 3 repeatedly utilizes the integration circuit composed of the subtractor 211, the multiplier 212, and the adder 214 and the integration circuit composed of the subtractor 231, the multiplier 232, and the adder 234, N/2 times to carry out signal processing similar to that carried out by a circuit with N cascaded integration circuits. Specifically, to perform a (J−1)th-order integration and a Jth-order (J is an even number of at least N) integration, the multiplexer 202 selects a (J−2)th integration signal as the recycle signal RCY. Then, the multiplexer 201 selects the recycle signal RCY as a selected input signal. Furthermore, the multiplexer 215 selects the (J−1)th-order integration signal corresponding to the preceding cycle, as an integrator feedback signal. The adder 214 then performs the (J−1)th-order integration. On the other hand, the multiplexer 235 selects the Jth-order integration signal corresponding to the preceding cycle, as an integrator feedback signal. The adder 234 then performs the Jth-order integration.

As described above, the sample rate converter according to the present embodiment repeatedly utilizes the two-stage loop filter N/2 times to fulfill a noise suppression capability equivalent to that of an N-th order loop filter. Therefore, the sample rate converter according to the present embodiment inhibits an increase in circuit area resulting from the increased order of the loop filter.

Furthermore, as shown in FIGS. 2 and 4, processing speed performance required for each of the multiplexers in the sample rate converter according to the present embodiment can be reduced to half that required in the first embodiment. Therefore, the sample rate converter according to the present embodiment can perform decimation on an input signal with a frequency higher than that available for the input signal according to the above-described first embodiment.

Additionally, the sample rate converter according to the present embodiment may be expanded. That is, in a modification of the sample rate converter according to the present embodiment, an M-stage loop filter may be utilized N/M times (N is a multiple of M).

### Third Embodiment

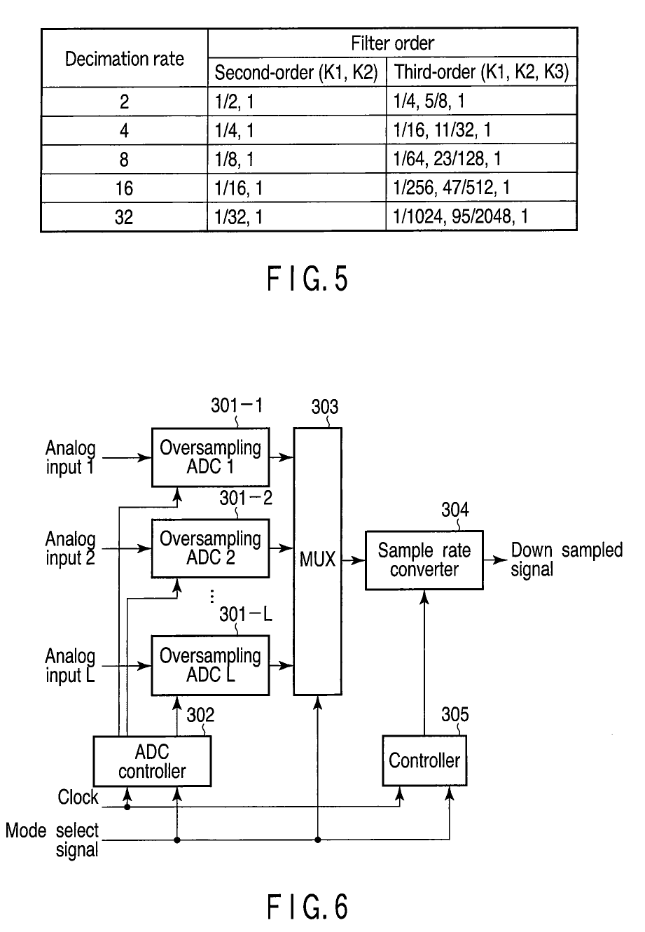

As shown in FIG. 6, a receiver according to a third embodiment of the present invention includes L (L is a natural number of at least 2) oversampling A/D converters 301-1 to 301-L, an ADC control unit 302, a multiplexer 303, a sample rate converter 304, and a sample rate converter control unit 305.

The receiver according to the present embodiment is compatible with L communication modes to carry out reception processing in one of the communication modes which corresponds to a mode selection signal generated by a control unit (not shown in the drawings). The receiver according to the present embodiment receives a radio signal by an antenna (not shown in the drawings). The radio signal received by the antenna is input to each of L reception RF processing units (not shown in the drawings). The reception RF processing units carry out a predetermined reception RF process on the input reception signal to obtain received baseband signals analog input 1 to analog input L. The L reception RF processing units input the received baseband signals analog input 1 to analog input L to oversampling A/D converters 301-1 to 301-L.

The oversampling A/D converters 301-1 to 301-L subject the received baseband signals analog input 1 to analog input L to analog-to-digital conversion at a sample rate sufficiently higher than a received baseband signal band.

The ADC control unit 302 provides an A/D converter control signal to each of the oversampling A/D converters 301-1 to 301-L. The ADC control unit 302 is controlled by a clock signal from the control unit (not shown in the drawings) to generate the A/D converter control signal according to a mode selection signal.

Digital received baseband signals from the oversampling A/D converters 301-1 to 301-L are input to the multiplexer 303, which selects one of the digital received baseband signals according to the mode selection signal.

The sample rate converter 304 is the sample rate converter according to the above-described first or second embodiment. The sample rate converter 304 performs sample rate conversion on the digital received baseband signal selected by the multiplexer 303.

The sample rate converter control unit 305 controls the sample rate converter 304. Specifically, the sample rate converter control unit 305 controls the decimation rate D of the sample rate converter 304, the filter order N, and the multiplier coefficient K according to the mode selection signal.

As described above, the receiver according to the present embodiment uses the sample rate converter according to the above-described first or second embodiment to perform the sample rate conversion corresponding to the communication mode. Therefore, the receiver according to the present embodiment eliminates the need for sample rate converters for the respective communication modes. The circuit area can thus be reduced.

### Fourth Embodiment

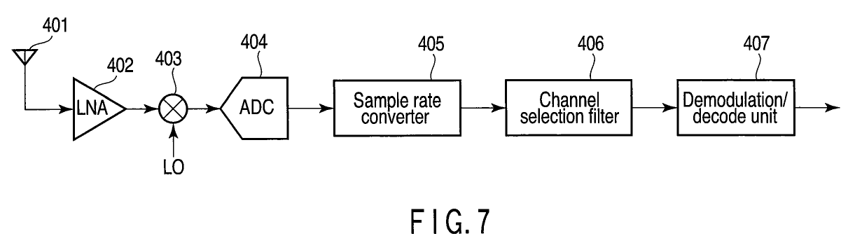

As shown in FIG. 7, a receiver according to a fourth embodiment of the present invention includes an antenna 401, a low noise amplifier (LNA) 402, a frequency converter 403, an analog-to-digital converter 404, a sample rate converter 405, a channel selection filter 406, and a demodulation/decode unit 407.

The antenna 401 receives a radio signal transmitted by a transmitter (not shown in the drawings) to input the received signal to LNA 402. LNA 402 amplifies the amplitude of the received signal from the antenna 401 at a predetermined amplification rate. LNA 402 then inputs the amplified signal to the frequency converter 403.

The frequency converter 403 includes a mixer and a low-pass filter (LPF). A mixer in the frequency converter 403 multiplies the amplified received signal from LNA 402 by a local signal LO for down conversion to obtain a summational frequency component and a differential frequency component. LPF in the frequency converter 403 extracts only one of the summational and differential frequency components, that is, the differential frequency component. LPF then inputs the differential frequency component to the analog-to-digital converter 404 as a received baseband signal.

The analog-to-digital converter 404 is an oversampling A/D converter. The analog-to-digital converter 404 subjects the received baseband signal from the frequency converter 403 to analog-to-digital conversion at a sample rate sufficiently higher than the received baseband signal band. The analog-to-digital converter 404 inputs the digital received baseband signal to the sample rate converter 405.

The sample rate converter 405 is the sample rate converter according to the above-described first or second embodiment. The sample rate converter 405 performs down sampling by changing the sample rate for the digital received baseband signal from the analog-to-digital converter 404, to the sample rate corresponding to the received baseband signal band. The sample rate converter 405 inputs the down-sampled digital received baseband signal to the channel selection filter 406.

The channel selection filter 406 removes interference waves with bands other than a desired one from the digital received baseband signal from the sample rate converter 405. The channel selection filter 406 inputs the digital received baseband signal from which the interference waves have been removed, to the demodulation/decode unit 407.

The demodulation/decode unit 407 demodulates the digital received baseband signal from the channel selection filter 406 according to a predetermined modulation scheme. The demodulation/decode unit 407 decodes the demodulated digital received baseband signal according to a predetermined encoding scheme to reproduce the received data.

As described above, the receiver according to the present embodiment uses the sample rate converter according to the above-described first or second embodiment. Therefore, the receiver according to the present embodiment enables inhibition of an increase in the area of the sample rate converter resulting from the increased order of the loop filter.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A sample rate converter performing Nth-order (N is a natural number of at least 2) integration on an input signal and then converting a sample rate for the input signal to generate an output signal, comprising:
a first selection unit configured to select either one of the input signal and a first feedback signal corresponding to an Mth-order (M is a natural number of 1≦M<N) integration signal repeatedly utilized to obtain an Nth-order integration signal, and to obtain a selected input signal;
a decimator performing decimation on the Nth-order integration signal according to a decimation rate to generate the output signal;
an interpolator performing interpolation corresponding to the decimation rate, on the output signal to generate a second feedback signal;
a second selection unit configured to sequentially select N coefficients one by one within a cycle corresponding to the sample rate to obtain a selected coefficient;
a multiplier which multiplies the second feedback signal by the selected coefficient to generate a multiplication signal;
a subtractor which subtracts the multiplication signal from the selected input signal to generate a residual signal;
an adder which adds the residual signal to a third feedback signal with an order greater than that of the selected input signal by one to sequentially generate 1st-order to Nth-order integration signals one by one;
a register circuit configured to hold the 1st-order to Nth-order integration signals;
a third selection unit configured to select the first feedback signal from the 1st-order to Nth-order integration signals that the register hold; and
a fourth selection unit configured to select the third feedback signal from the 1st-order to Nth-order integration signals that the register hold.

2. The sample rate converter according to claim 1, wherein the register circuit includes N flip flops each holding a corresponding one of the 1st-order to Nth-order integration signals.

3. The sample rate converter according to claim 1, wherein the N coefficients are set according to the decimation rate.

4. A sample rate converter performing Nth-order (N is an even number of at least 4) integration on an input signal and then converting a sample rate for the input signal to generate an output signal, comprising:
a first selection unit configured to select either one of the input signal and a first feedback signal corresponding to an Mth-order (M is an even number of 1≦M<N) integration signal repeatedly utilized to obtain an Nth-order integration signal, and to obtain a selected input signal;
a decimator performing decimation on the Nth-order integration signal according to a decimation rate to generate the output signal;
an interpolator performing interpolation corresponding to the decimation rate, on the output signal to generate a second feedback signal;
a second selection unit configured to sequentially select N/2 coefficients one by one within a cycle corresponding to the sample rate to obtain a first selected coefficient;
a first multiplier which multiplies the second feedback signal by the first selected coefficient to generate a first multiplication signal;
a first subtractor which subtracts the first multiplication signal from the selected input signal to generate a first residual signal;
a first adder which adds the first residual signal to a third feedback signal with an order greater than that of the selected input signal by one to sequentially generate odd number-order integration signals one by one;
a first register circuit configured to hold the odd number-order integration signals;
a third selection unit configured to select the third feedback signal from the odd number-order integration signals that the first register hold;
a fourth selection unit configured to sequentially select N/2 second coefficients one by one within the cycle to obtain a second selected coefficient;
a second multiplier which multiplies the second feedback signal by the second selected coefficient to generate a second multiplication signal;
a second subtractor which subtracts the second multiplication signal from each of the odd number-order integration signals to generate a second residual signal;
a second adder which adds the second residual signal to a fourth feedback signal with an order greater than that of each of the odd number-order signals by one to sequentially generate even number-order integration signals one by one;
a second register circuit configured to hold the even number-order integration signals;
a fifth selection unit configured to select the fourth feedback signal from the even number-order integration signals that the second register hold; and
a sixth selection unit configured to select the first feedback signal from the even number-order integration signals.

5. The sample rate converter according to claim 4, wherein the first register circuit includes N/2 flip flops each holding a corresponding one of the odd number-order integration signals, and
the second register circuit includes N/2 flip flops each holding a corresponding one of the even number-order integration signals.

6. The sample rate converter according to claim 4, wherein the N/2 first coefficients and the N/2 second coefficients are set according to the decimation rate.

7. A receiver configured to support a plurality of communication modes, comprising:
a plurality of analog-to-digital converters which subject a respective plurality of analog signals corresponding to the respective plurality of communication modes to analog-to-digital conversion to obtain a plurality of digital signals;
a selection unit configured to select any one of the plurality of digital signals according to a selected one of the plurality of communication modes; and
the sample rate converter according to claim 1 which receives the selected digital signal as the input signal.

8. The receiver according to claim 7, further comprising:
a reception unit configured to carry out reception processing corresponding to the individual communication modes, on a received radio signal to generate the plurality of analog signals;
a filter which filters an output signal from the sample rate converter to remove an interference wave from the output signal to generate a filtered signal; and
a demodulation/decode unit configured to perform demodulation and decoding on the filtered signal to reproduce received data.

9. A receiver configured to support a plurality of communication modes, comprising:
a plurality of analog-to-digital converters which subject a respective plurality of analog signals corresponding to the respective plurality of communication modes to analog-to-digital conversion to obtain a plurality of digital signals;
a selection unit configured to select any one of the plurality of digital signals according to a selected one of the plurality of communication modes; and
the sample rate converter according to claim 4 which receives the selected digital signal as the input signal.

10. The receiver according to claim 9, further comprising:
a reception unit configured to carry out reception processing corresponding to the individual communication modes, on a received radio signal to generate the plurality of analog signals;
a filter which filters an output signal from the sample rate converter to remove an interference wave from the output signal to generate a filtered signal; and
a demodulation/decode unit configured to perform demodulation and decoding on the filtered signal to reproduce received data.
